(19) United States
(12) Patent Application Publication
(10) Pub. No.: US 2009/0235980 A1
(43) Pub. Date: Sep. 24, 2009

(54) SOLAR CELL MANUFACTURING METHOD AND SOLAR CELL

(75) Inventor: Toyozo NISHIDA, Takarazuka City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi City (JP)

(21) Appl. No.: 12/372,029

(22) Filed: Feb. 17, 2009

(30) Foreign Application Priority Data
Mar. 19, 2008 (JP) JP2008-072500

(51) Int. Cl. H01L 31/00; B05D 5/12

(52) U.S. Cl. 136/256; 427/74; 427/554

(57) ABSTRACT

An aspect of the invention provides a solar cell manufacturing method that comprises the steps of: forming a porous layer, having a plurality of pores, on a photoelectric conversion body configured to generate photo-generated carriers upon receipt of light; and forming an electrode by disposing a conductive material on the porous layer, the conductive material infiltrating the porous layer to thereby make contact with the photoelectric conversion body.

### CROSS REFERENCE TO RELATED APPLICATIONS

This application claims priority based on 35 USC 119 from prior Japanese Patent Application No. P2008-072500 filed on Mar. 19, 2008, entitled “Solar cell manufacturing method and solar cell”, the entire contents of which are incorporated herein by reference.

### BACKGROUND OF THE INVENTION

1. Field of the Invention

The present invention relates to a manufacturing method of a solar cell including a plurality of fine line-shaped electrodes provided on a photoelectric conversion body and to the solar cell.

2. Description of Related Art

Solar cells directly convert solar energy, which is non-polluting and unlimited in supply, to electric energy, and are therefore attractive as a new energy source.

In general, a solar cell includes a photoelectric conversion body, which generates carriers upon absorption of light, and a plurality of fine line-shaped electrodes, which collect the photo-generated carriers from the photoelectric conversion body. For example, Japanese Patent Application Publication No. 2005-116786 discloses formation of fine line-shaped electrodes on a photoelectric conversion body by disposing a conductive paste onto the converter surface using a printing method or other application methods.

In order to increase the light-absorbing area of the photoelectric conversion body, it is preferable to form the line-shaped electrode as narrow as possible. In order to minimize the electric resistance of the fine line-shaped electrode, it is preferable to form the line-shaped electrode as thick as possible.

A low viscosity conductive paste needs to be used for forming a fine line-shaped electrode using a printing method or other application method. However such a low viscosity conductive paste tends to spread on the photoelectric conversion body, thereby making it difficult to form a thicker, more conductive, line-shaped electrode.

### SUMMARY OF THE INVENTION

One embodiment of the invention provides a solar cell manufacturing method that comprises the steps of: forming a porous layer, having a plurality of pores, on a photoelectric conversion body configured to produce photo-generated carriers upon absorption of light; and forming on the porous layer an electrode by disposing a conductive material on the porous layer, the conductive material infiltrating the porous layer to thereby make contact with the photoelectric conversion body. The pores of the porous layer may be predominately in the direction through the porous layer as opposed to lateral to the layer. The conducting material deposited on the porous layer in a narrow line therefore infiltrates the porous layer to contact the photoelectric conversion body without significant lateral spread.

This minimizes spread of the low viscosity conducting material on the porous layer, thereby minimizing the width of the electrode. Since the conductive material infiltrates the porous layer, the thickness of the electrode and therefore its conductivity can be maximized. Hence, a conductive material having a low viscosity can be used to form an electrode with a narrow width and low electric resistance.

Another embodiment of the invention provides a solar cell that comprises a photoelectric conversion body configured to generate photo-generated carriers upon absorption of light; a porous layer provided on the photoelectric conversion body and including a plurality of pores; and an electrode provided on the photoelectric conversion body, wherein the electrode makes contact with the photoelectric conversion body through the pores in the porous layer.

Another embodiment of the invention provides a solar cell that comprises a photoelectric conversion body configured to generate photo-generated carriers upon absorption of light; and an electrode provided on the photoelectric conversion body, wherein the electrode includes a plurality of pores.

### BRIEF DESCRIPTION OF THE DRAWING

FIG. 1 is a plan view of the light receiving surface of solar cell 10 according to a first embodiment.

FIG. 2 is an enlarged cross-sectional view cut along the line A-A of FIG. 1.

FIG. 3 is an enlarged cross-sectional view of solar cell 10 according to modification 1 of the first embodiment.

FIG. 4 is an enlarged cross-sectional view of solar cell 10 according to modification 2 of the first embodiment

FIG. 5 is a plan view of the light receiving surface of solar cell 20 according to a second embodiment.

FIG. 6 is an enlarged cross-sectional view cut along the line B-B of FIG. 5.

FIGS. 7A and 7B illustrate a process of manufacturing solar cell 20 according to the second embodiment.

### DETAILED DESCRIPTION OF EMBODIMENTS

The present invention is described below in more detail on the basis of embodiments. However, the invention is not limited to the embodiments to be described below and can be implemented by being changed, as needed, without deviating from the gist of the invention.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

### First Embodiment

<Construction of Solar Cell>

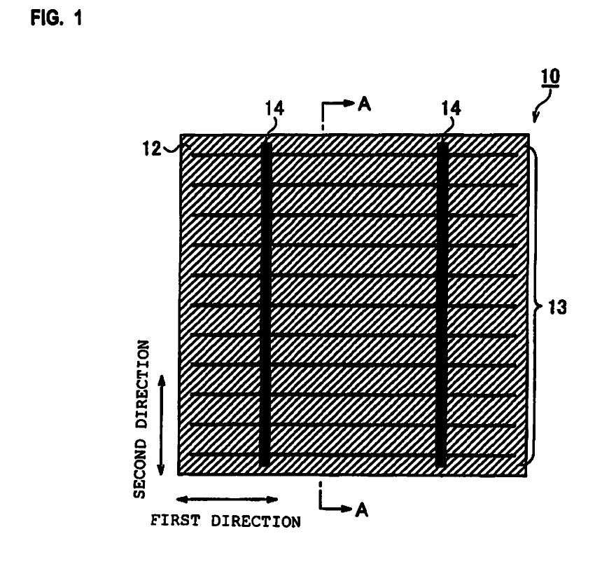

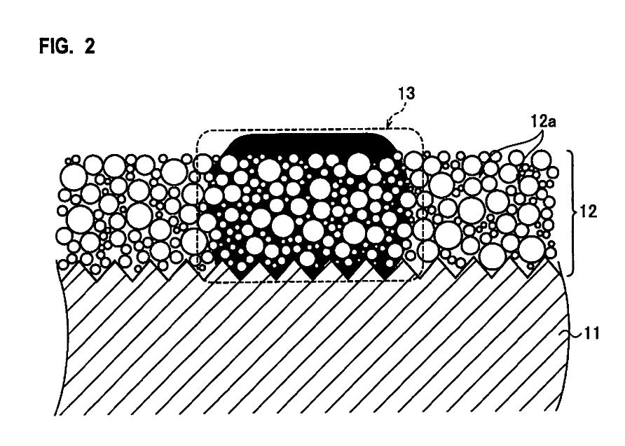

A schematic construction of solar cell 10 according to a first embodiment will be described below with reference to FIGS. 1 and 2. FIG. 1 is a plan view of the light receiving surface of solar cell 10. FIG. 2 is an enlarged cross-sectional view cut along the line A-A of FIG. 1.

Solar cell 10 includes photoelectric conversion body 11, porous layer 12, electrode 13 and connecting electrodes 14 as shown in FIGS. 1 and 2.

Photoelectric conversion body 11 has a light receiving surface (upper surface in FIG. 2) and a back surface (not shown) provided on the opposite side to the light receiving surface. The light receiving surface and the back surface are the major surfaces of solar cell 10.

When light is absorbed at the light receiving surface and the back surface of photoelectric conversion body 11, photo-generated carriers are generated in the form of hole electron pairs. Photoelectric conversion body 11 has a p type region and an n type region therein (not shown). A semiconductor junction is formed at an interface between the p type region and the n type region in photoelectric conversion body 11. Photoelectric conversion body 11 can be formed by using a semiconductor substrate made of a semiconductor material including: a crystalline semiconductor material such as single crystal Si and polycrystalline Si; a compound semiconductor material such as GaAs and InP; and the like. Photoelectric conversion body 11 may have a structure in which a substantially intrinsic amorphous silicon layer is sandwiched between single crystal silicon substrate and an amorphous silicon layer to improve the characteristics of a heterojunction interface, i.e., a so-called HIT structure.

Porous layer 12 is provided on the light receiving surface of photoelectric conversion body 11. Porous layer 12 has plurality of pores 12a. Porous layer 12 is made of, for example, a particulate metal oxide. A plurality of pores 12a are formed among the particles of the metal oxide. As such a metal oxide, a translucent conductive material such as indium oxide (In₂O₃), zinc oxide (ZnO), tin oxide (SnO₂) and titanium oxide (TiO₂) can be used. However, the metal oxide is not limited to these materials. These translucent conductive materials may be doped with a dopant such as fluorine (F), aluminum (Al), titanium (Ti), iron (F), zinc (Zn), gallium (Ga), niobium (Nb), tin (Sn), antimony (Sb), and tungsten (W). Porous layer 12 may have a thickness of approximately 10 μm to 100 μm. Each pore 12a may have a diameter of approximately 0.1 μm to 100 μm, preferably, a diameter of approximately 1 μm to 100 μm. In the first embodiment, porous layer 12 is preferably formed to have a thickness smaller than the width of electrode 13 so that a conductive paste disposed on porous layer 12 can reach the light receiving surface of photoelectric conversion body 11. When electrode 13 is to be formed to have a width of, for example, 30 μm, porous layer 12 can be formed to have a thickness of 20 μm. Note that the width of electrode 13 refers to the maximum value of the width of electrode 13 in the second direction as indicated in FIG. 1.

Electrode 13 is a collecting electrode for collecting photo-generated carriers from photoelectric conversion body 11. Electrode 13 may be a fine line-shaped electrode. In this embodiment, solar cell 10 includes a plurality of fine line-shaped electrodes 13 as shown in FIG. 1. Fine line-shaped electrode 13 is formed, on the light receiving surface of photoelectric conversion body 11, along a first direction substantially parallel to one side of photoelectric conversion body 11 as shown in FIGS. 1 and 2. A plurality of fine line-shaped electrodes 13 are disposed in parallel with one another in the second direction that is substantially perpendicular to the first direction.

As shown in FIG. 2, fine line-shaped electrode 13 is deposited on porous layer 12 and infiltrates the pores 12a of porous layer 12 to make contact with the light receiving surface of photoelectric conversion body 11.

Fine line-shaped electrode 13 can be formed by disposing a conductive paste on porous layer 12. Examples of the conductive paste adaptable herein include: a resin-type conductive paste in which a resin material is used as a binder and conductive particles such as silver particles are used as a filler; and a sintered-type conductive paste (so-called ceramic paste) containing conductive particles such as silver powders, glass frits, an organic vehicle, an organic solvent, or the like. These conductive pastes can be disposed on porous layer 12 by using a printing method such as an inkjet method, a dispensing method, or the like. When the conductive paste is disposed on porous layer 12 by using the printing method such as an inkjet method, the diameter of the conductive particle contained in the conductive paste can be approximately 10 nm to 100 nm. Meanwhile, when the conductive paste is disposed on porous layer 12 by using the dispensing method, the diameter of the conductive particle contained in the conductive paste can be approximately 10 nm to 5 μm. The diameter of the conductive particle is preferably one-tenth or less of the diameter of a plurality of pores 12a included in porous layer 12. The dimension and number of fine line-shaped electrode 13 can suitably be set in consideration of the size of photoelectric conversion body 11, and so forth.

Connecting electrode 14 is an electrode connected to a wire (not shown) electrically connecting a plurality of solar cells 10 in series or in parallel. Connecting electrode 14 is formed along the second direction on the light receiving surface of photoelectric conversion body 11 as shown in FIG. 1. Therefore, connecting electrode 14 intersects a plurality of fine line-shaped electrodes 13 and is electrically connected to a plurality of fine line-shaped electrodes 13.

Connecting electrode 14 is deposited on the light receiving surface of photoelectric conversion body 11 by the same process as fine line-shaped electrode 13. Although not depicted in a figure, connecting electrode 14 makes contact with the light receiving surface of photoelectric conversion body 11 by the same process as fine line-shaped electrodes 13 that is by infiltrating the pores of porous layer. Connecting electrode 14 can be formed by the printing method, the dispensing method, or the like, just as fine line-shaped electrode 13. The dimension and number of connecting electrode 14 can suitably be set in consideration of the size of photoelectric conversion body 11, and so forth.

Fine line-shaped electrodes 13 and connecting electrodes 14, which have the same shapes as fine line-shaped electrodes 13, can also be formed on the back surface of photoelectric conversion body 11. However, the present invention is not limited to the above configuration. For example, fine line-shaped electrodes 13 may be formed to cover almost the entire back surface of photoelectric conversion body 11. The present invention is not meant to limit the shape of fine line-shaped electrode 13 and connecting electrode 14 which may be formed on the back surface of photoelectric conversion body 11.

<Manufacturing Method of Solar Cell>

Next, a manufacturing method of solar cell 10 according to the first embodiment will be described.

First, a 100 mm square n type single crystal silicon substrate is etched to form minute irregularities on the light receiving surface of the n type single crystal silicon substrate. Then, an i type amorphous silicon layer and a p type amorphous silicon layer are sequentially stacked on the light receiving surface of the n type single crystal silicon substrate by using a CVD (Chemical Vapor Deposition) method. Similarly, an i type amorphous silicon layer and an n type amorphous silicon layer are sequentially stacked on the back surface of the n type single crystal silicon substrate. The layered structure just described comprises photoelectric conversion body 11. Irregularities similar to those formed on the light receiving surface of the n type single crystal silicon substrate are also formed on the light receiving surface of photoelectric conversion body 11.

Porous layer 12 having a plurality of pores 12a is then formed on the light receiving surface of photoelectric conversion body 11. To be specific, particles made of a translucent conductive material are disposed on the light receiving surface of photoelectric conversion body 11 to thereby form porous layer 12 having pores 12a.

Then, a conductive paste is disposed on porous layer 12 in a predetermined pattern by using a printing method or a dispensing method. The predetermined pattern refers to a shape corresponding to fine line-shaped electrodes 13 extending along a first direction and connecting electrodes 14 extending along a second direction as shown in FIG. 1. The conductive paste is a material for forming fine line-shaped electrode 13 and connecting electrode 14.

The conductive paste disposed on porous layer 12 passes through pores 12a by a capillary action, infiltrates porous layer 12, and then contacts the light receiving surface of photoelectric conversion body 11. Subsequently, the conductive paste is dried to volatilize a solvent remaining in the conductive paste. The conductive paste is then heated to be fixed. Through these processes, fine line-shaped electrodes 13 and connecting electrodes 14, which are provided on the light receiving surface of photoelectric conversion body 11, pass through a plurality of pores 12a included in porous layer. In this manner, solar cell 10 according to the first embodiment is manufactured.

In the manufacturing method of solar cell 10 according to the first embodiment, porous layer 12 is formed on the light receiving surface of photoelectric conversion body 11, and then the conductive paste for forming fine line-shaped electrode 13 is disposed on porous layer 12. The conductive paste passes through a plurality of pores 12 included in porous layer 12, and contacts the light receiving surface of photoelectric conversion body 11.

According to such a manufacturing method of solar cell 10, the conductive paste disposed on porous layer 12 infiltrates porous layer 12 to contact the light receiving surface of photoelectric conversion body 11 with minimal lateral spreading on porous layer 12. Accordingly, fine line-shaped electrode 13 can be formed with a very narrow width. Moreover, the conductive paste infiltrates porous layer 12, whereby fine line-shaped electrode 13 can be formed to be quite thick. Thus, even if fine line-shaped electrode 13 is formed to have a narrow width, the cross-sectional area of fine line-shaped electrode 13 can be maintained to be large. The electric resistance of fine line-shaped electrode 13 can therefore be maintained to be low. According to the present invention, fine line-shaped electrode 13 with a small width and low electric resistance can thus be formed.

Moreover, according to the first embodiment manufacturing method of solar cell 10, the conductive paste can be prevented from spreading laterally on the light receiving surface of photoelectric conversion body 11. Accordingly, fine line-shaped electrode 13 can be formed with a narrow width despite the irregularities formed on the light receiving surface photoelectric conversion body 11.

Furthermore, use of the translucent conductive material as porous layer 12 eliminates a need to separately form a translucent conductive film, to transport photo-generated carriers generated in photoelectric conversion body 11, between photoelectric conversion body 11 and fine line-shaped electrode 13. The manufacturing steps of solar cell 10 can consequently be simplified.

### Modification 1 of First Embodiment

Hereinafter, solar cell 10 according to modification 1 of the first embodiment will be described. Although, in the above-described first embodiment, a particulate metal oxide is used as porous layer 12, the present invention is not limited to this. For example, an organic material including air bubbles as pores 12a may be used as porous layer 12. An example of such an organic material adaptable herein is a resin material such as polyethylene, polydimethylsiloxane, epoxy, styrene-divinylbenzene, polystyrene, and polycarbonate. Air bubbles can be included in these resin materials by stirring the resin materials. Alternatively, air bubbles may be included in the resin materials by impregnating a foaming agent into the resin material and then heating the resin material impregnated with the foaming agent up to a foaming temperature.

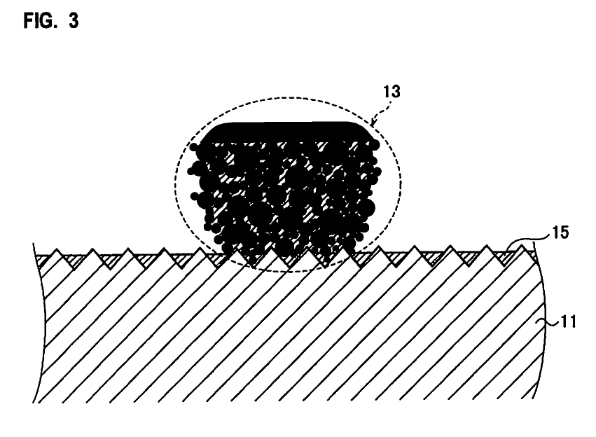

When such an organic material is used as porous layer 12, porous layer 12 is pressurized in the process of heating and thus fixing the conductive paste. Thereby, pores 12a are removed from the organic material. As a result, organic layer 15 is formed as shown in FIG. 3.

It is generally known that moisture tends to accumulate at the interface between porous layer 12 and photoelectric conversion body 11. For this reason, in solar cell 10 according to modification 1 of the first embodiment, pores 12a are removed from the organic material to prevent moisture from moving into the organic material. Accordingly, moisture can be prevented from accumulating at the interface between porous layer 12 and photoelectric conversion body 11. Consequently, the light receiving surface of photoelectric conversion body 11 can be prevented from being deteriorated.

### Modification 2 of First Embodiment

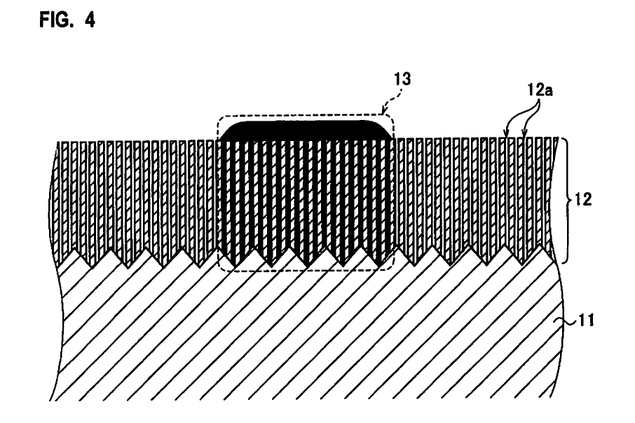

Hereinafter, solar cell 10 according to modification 2 of the first embodiment will be described. Although porous layer 12 includes pores 12a formed among the metal oxide particles forming porous layer 12 in the above-described first embodiment, the present invention is not limited to this. For example, as shown in FIG. 4, porous layer 12 may include a plurality of through-holes, as pore 12a, formed in a direction substantially perpendicular to the light receiving surface of photoelectric conversion body 11 by a laser method or the like.

The formation of such pores 12a in porous layer 12 in the direction substantially perpendicular to the light receiving surface of photoelectric conversion body 11 results in much less lateral spreading compared to, for example, cases where pores 12a are gaps formed among the metal oxide particles or where pores 12a are air bubbles arranged at random. Therefore, fine line-shaped electrode 13 can be formed with an even narrower width. Furthermore, the width of fine line-shaped electrode 13 can be maintained to be small, even when porous layer 12 is formed to a large thickness. Accordingly, increasing the thickness of porous layer 12 makes it possible to form fine line-shaped electrode 13 to a large thickness and a narrow width.

### Second Embodiment

Hereinafter, solar cell 20 according to a second embodiment will be described. The difference between the foregoing first embodiment and the second embodiment will be mainly described below.

<Construction of Solar Cell>

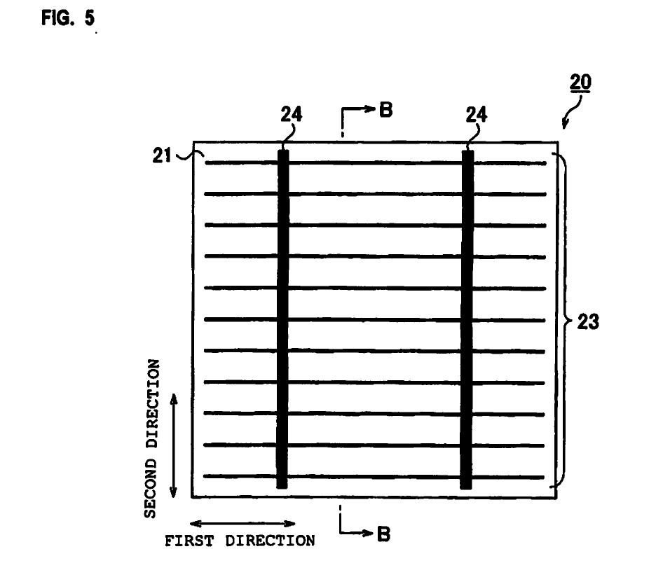

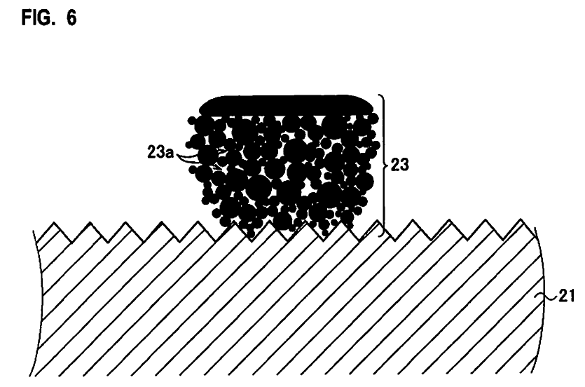

A schematic depiction of solar cell 20 according to the second embodiment will be described with reference to FIGS. 5 and 6. FIG. 5 is a plan view of the light receiving surface of solar cell 20. FIG. 6 is a cross-sectional view taken along the line A-A of FIG. 5.

Solar cell 20 includes photoelectric conversion body 21, fine line-shaped electrodes 23 and connecting electrodes 24 as shown in FIGS. 5 and 6. The construction of photoelectric conversion body 21 is almost the same as that of photoelectric conversion body 11 according to the first embodiment described above. Accordingly, the description thereof is here omitted.

Fine line-shaped electrode 23 is a collecting electrode for collecting photo-generated carriers from photoelectric conversion body 21. Fine line-shaped electrode 23 is formed, on the light receiving surface of photoelectric conversion body 21, along a first direction as shown in FIGS. 5 and 6. A plurality of fine line-shaped electrodes 23 are disposed in parallel with one another in a second direction substantially perpendicular to the first direction.

As shown in FIG. 6, fine line-shaped electrode 23 is provided on the light receiving surface of photoelectric conversion body 21, and has a plurality of pores 23a. Pores 23a of fine line-shaped electrode 23 correspond to porous layer 22 (described hereinafter) having a plurality of pores 22a.

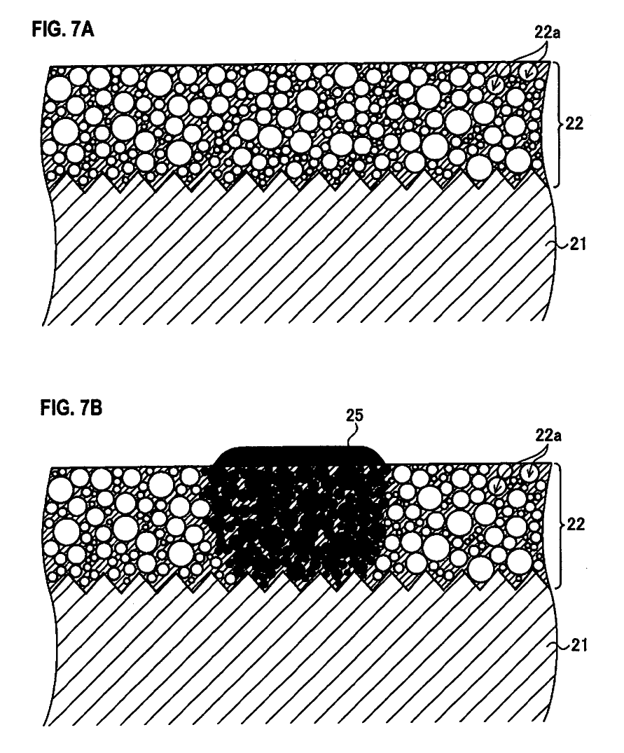

Fine line-shaped electrode 23 can be formed by disposing conductive paste 25 (refer to FIG. 7) on porous layer 22 (refer to FIG. 7) to be described later. Examples of conductive paste 25 adaptable herein include: a resin-type conductive paste in which a resin material is used as a binder and conductive particles such as silver particles are used as a filler; and a sintered-type conductive paste (so-called ceramic paste) containing conductive particles such as silver powders, glass frits, an organic vehicle, an organic solvent, or the like. These types of conductive pastes 25 can be disposed on porous layer 22 by using a printing method such as an inkjet method, a dispensing method, or the like. When conductive paste 25 is disposed on porous layer 22 by using the printing method such as an inkjet method, the diameter of the conductive particle contained in conductive paste 25 can be 10 nm to 100 nm. Meanwhile, when conductive paste 25 is disposed on porous layer 22 by using the dispensing method, the diameter of the conductive particle contained in conductive paste 25 can be 10 nm to 5 μm. The diameter of the conductive particle is preferably one-tenth or less of the diameter of a plurality of pores 22a included in porous layer 22. The dimension and number of fine line-shaped electrode 23 can suitably be set in consideration of the size of photoelectric conversion body 21, and so forth.

Connecting electrode 24 is an electrode connected to a wire (not shown) electrically connecting a plurality of solar cells 10 in series or in parallel. Connecting electrode 24 is formed along the second direction on the light receiving surface of photoelectric conversion body 21 as shown in FIG. 5. Therefore, connecting electrode 24 intersects a plurality of fine line-shaped electrodes 23 and is electrically connected to a plurality of fine line-shaped electrodes 23.

Connecting electrode 24 is provided on the light receiving surface of photoelectric conversion body 21 by the same process as fine line-shaped electrode 23. Connecting electrode 24 has a plurality of pores (not shown). The pores of connecting electrode 24 correspond to porous layer 22 (described hereinafter) having a plurality of pores 22a. Connecting electrode 24 can be formed by the printing method, the dispensing method, or the like, just as fine line-shaped electrode 23. The dimension and number of connecting electrode 24 can suitably be set in consideration of the size of photoelectric conversion body 21, and so forth.

<Manufacturing Method of Solar Cell>

Next, a manufacturing method of solar cell 20 according to the second embodiment will be described with reference to FIGS. 7A and 7B. Photoelectric conversion body 21 is first produced in the same manner as in the foregoing first embodiment.

Then, porous layer 22 having a plurality of pores 22a is formed on the light receiving surface of photoelectric conversion body 21. To be specific, as shown in FIG. 7A, an organic material including air bubbles as pores 22a is disposed on the light receiving surface of photoelectric conversion body 21. The organic material is to serve as porous layer 22. An example of such an organic material adaptable herein is a resin material decomposed by heating such as polyethylene, epoxy, styrene-divinylbenzene, polystyrene, and polycarbonate. Air bubbles can be included in these resin materials by stirring the resin materials. Alternatively, air bubbles may be included in the resin materials by impregnating a foaming agent into the resin material and the heating the resin material impregnated with the foaming agent up to a foaming temperature.

Then, conductive paste 25 is disposed on porous layer 22 in a predetermined pattern by a printing method or a dispensing method. The predetermined pattern refers to a shape corresponding to fine line-shaped electrodes 23 extending along a first direction and connecting electrodes 24 extending along a second direction as shown in FIG. 5. Conductive paste 25 is a material for forming fine line-shaped electrode 23 and connecting electrode 24.

Conductive paste 25 disposed on porous layer 22 passes through pore 22a by a capillary action as shown in FIG. 7B, infiltrates porous layer 22, and then contacts the light receiving surface of photoelectric conversion body 21. Subsequently, conductive paste 25 is dried to volatilize a solvent remaining in conductive paste 25. Porous layer 22 and conductive paste 25 are then heated to thermally oxidize the organic material for forming porous layer 22 and to fix conductive paste 25. Thereby, porous layer 22 is removed. Thereby, fine line-shaped electrode 23 having a plurality of pores 23a corresponding to porous layer 22 and connecting electrode 24 having a plurality of pores corresponding to porous layer 22 are formed on the light receiving surface of photoelectric conversion body 21 as shown in FIG. 6. In this manner, solar cell 20 according to the second embodiment is manufactured.

In the manufacturing method of solar cell 20 according to the second embodiment, porous layer 22 is formed on the light receiving surface of photoelectric conversion body 21, and then conductive paste 25 for forming fine line-shaped electrode 23 is disposed on porous layer 22. Conductive paste 25 passes through a plurality of pores 22a included in porous layer 22, and reaches the light receiving surface of photoelectric conversion body 21. Thereby, fine line-shaped electrode 23 with a narrow width and low electric resistance can be formed.

Moreover, in the manufacturing method of solar cell 20 according to the second embodiment, after conductive paste 25 passes through a plurality of pores 22a included in porous layer 22 and reaches the light receiving surface of photoelectric conversion body 21, porous layer 22 is removed.

As mentioned above, it is generally known that moisture tends to accumulate at the interface between porous layer 22 and photoelectric conversion body 21. For this reason, in solar cell 20 according to the second embodiment, porous layer 22 is removed, after conductive paste 25 passes through a plurality of pores 22a included in porous layer 22 and contacts the light receiving surface of photoelectric conversion body 21. This prevents moisture from accumulating at the interface between porous layer 22 and photoelectric conversion body 21. Consequently, the light receiving surface of photoelectric conversion body 21 can be prevented from being deteriorated due to the moisture accumulation.

### Modification of Second Embodiment

Hereinafter, modification of the second embodiment will be described. Although conductive paste 25 infiltrating porous layer 22 is fixed to form fine line-shaped electrode 23 having a plurality of pores 23a corresponding to porous layer 22 in the foregoing second embodiment, the present invention is not limited to this. For example, a conductive material may be caused to infiltrate pores 23a of fine line-shaped electrode 23 formed by fixing conductive paste 25 to thereby fill pores 23a of fine line-shaped electrode 23 with the conductive material.

By filling pores 23a of fine line-shaped electrode 23 with the conductive material, the electric resistance of fine line-shaped electrode 23 can further be reduced.

### Other Embodiments

Although the present invention has been described on the basis of the aforementioned embodiments, it should be understood that the descriptions and drawings that constitute parts of this disclosure do not limit the present invention. Various alternative embodiments, examples and operation technologies will be apparent from the disclosure to those skilled in the art.

For example, in the aforementioned first and second embodiments, formation of irregularities on the light receiving surface of a photoelectric conversion body was described. However, the present invention is limited to this. Irregularities may not be formed on the light receiving surface of a photoelectric conversion body.

Moreover, in the aforementioned second embodiment, although the description has been given of the case where an organic material including air bubbles as pores is used as a porous layer, the present invention is not limited to this. An organic material including hollow organic particles in addition to air bubbles may be used as a porous layer. The use of such an organic material including hollow organic particles allows a time required to thermally oxidize the organic material to be reduced. Accordingly, the porous layer can be removed more simply.

Furthermore, in the aforementioned first and second embodiments, the present invention is applied to a crystalline solar cell. However, the present invention may also be applied to a thin-film solar cell. To be specific, as in the aforementioned first and second embodiment, it is possible to form a fine line-shaped electrode with a small width and low electric resistance in a manufacturing method of a thin-film solar cell including a substrate, a first conductive film, a photoelectric conversion body and a fine line-shaped electrode sequentially stacked in this order. In this manufacturing method, a second translucent conductive film having a plurality of pores is formed on the photoelectric conversion body, and a conductive material for forming the fine line-shaped electrode is disposed on the second translucent conductive film. Thereby, such a fine line-shaped electrode with a small width and low electric resistance is formed on the photoelectric conversion body. Note that, the photoelectric conversion body in such a thin-film solar cell generates photo-generated carriers by light entering from the fine line-shaped electrode toward the substrate.

As have been described above, the aforementioned embodiments can provide: a manufacturing method of a solar cell including a fine line-shaped electrode with a narrow width and low electric resistance; and such a solar cell.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell manufacturing method comprising the steps of:
forming a porous layer having a plurality of pores, on a photoelectric conversion body configured to generate photo-generated carriers upon receipt of light; and
forming an electrode by disposing a conductive material on the porous layer, the conductive material infiltrating the porous layer to thereby contact the photoelectric conversion body.

2. The manufacturing method of claim 1, wherein the porous layer is made of a metal oxide material.

3. The manufacturing method of claim 1, wherein the porous layer is made of a translucent metal oxide material.

4. The manufacturing method of claim 1, wherein the porous layer is made of a particulate metal oxide material.

5. The manufacturing method of claim 1, wherein the porous layer includes at least one selected from indium oxide (In₂O₃), zinc oxide (ZnO), tin oxide (SnO₂) and titanium oxide (TiO₂).

6. The manufacturing method of claim 1, wherein the porous layer includes at least one selected from fluorine (F), aluminium (Al), titanium (Ti), iron (Fe), zinc (Zn), gallium (Ga), niobium (Nb), tin (Sn), antimony (Sb) and tungsten (W).

7. The manufacturing method of claim 1, wherein the pores each have a size of 0.1 μm to 100 μm inclusive.

8. The manufacturing method of claim 1, wherein the porous layer is made of an organic material including air bubbles.

9. The manufacturing method of claim 8, wherein the organic material includes at least one resin material selected from polyethylene, polydimethylsiloxane, epoxy, styrene-divinylbenzene, polystyrene, and polycarbonate.

10. The manufacturing method of claim B, wherein the air bubbles are included in the resin material by stirring the resin material.

11. The manufacturing method of claim 8, wherein the air bubbles are included in the resin material by impregnating a foaming agent into the resin material and then heating the resin material impregnated with the foaming agent up to a foaming temperature.

12. The manufacturing method of claim 8, further comprising:
heating and thus fixing the fine line-shaped electrodes; and
pressurizing the porous layer to remove pores from the porous layer.

13. The manufacturing method of claim 1, wherein the plurality of pores are formed by a laser method as a plurality of through-holes in the porous layer in a direction substantially perpendicular to a light receiving surface of the photoelectric conversion body.

14. The manufacturing method of claim 1, wherein the conductive material is any one of: a resin-type conductive paste using conductive particles as a filler; and a sintered-type conductive paste containing any of conductive particles, glass frits, an organic vehicle and an organic solvent.

15. A solar cell comprising:
a photoelectric conversion body configured to generate photo-generated carriers upon exposure to light;
a porous layer provided on the photoelectric conversion body and including a plurality of pores; and
an electrode provided on the photoelectric conversion body, wherein
the electrode contacts the photoelectric conversion body through the pores in the porous layer.

16. The solar cell of claim 15, wherein the porous layer is made of a translucent metal oxide material.

17. The solar cell of claim 15, wherein the porous layer is provided on a light receiving surface of the photoelectric conversion body.

18. A solar cell comprising:
a photoelectric conversion body configured to generate photo-generated carriers upon exposure to light; and
an electrode provided on the photoelectric conversion body, wherein
the electrode includes a plurality of pores.

19. The solar cell of claim 18, wherein the electrode is provided on a light receiving surface of the photoelectric conversion body.

20. The solar cell of claim 18, wherein the plurality of pores included in the electrode is filled with a conductive material.
